(19) United States
(12) Patent Application Publication
(10) Pub. No.: US 2020/0027801 A1
(43) Pub. Date: Jan. 23, 2020

(54) TEST STRUCTURE FOR INLINE DETECTION OF INTERLAYER METAL DEFECTS

(71) Applicant: QUALCOMM Incorporated, San Diego, CA (US)

(72) Inventors: Fadoua CHAFIK, San Diego, CA (US); Samit SENGUPTA, San Diego, CA (US)

(21) Appl. No.: 16/248,579

(22) Filed: Jan. 15, 2019

Related U.S. Application Data
(60) Provisional application No. 62/700,785, filed on Jul. 19, 2018.

(51) Int. Cl. H01L 21/66; H01L 23/522; H01L 23/528; H01L 21/311; H01L 21/768

(52) U.S. Cl. CPC H01L 22/32; H01L 23/5226; H01L 21/76877; H01L 21/31116; H01L 21/76816; H01L 23/528

(57) ABSTRACT

A integrated circuit structure has a first test structure with a first set of un-landed vias. The first set of un-landed vias has a first side for each of the first set of un-landed vias proximate to a first BEOL layer (first back-end-of-line layer) of a chip and spaced apart, by a first gap, from the first BEOL layer. Each of the first set of un-landed vias has a first depth that is smaller than a landed depth of a chip via conductively connecting the first BEOL layer to a second BEOL layer of the chip. The first set of un-landed vias also has a second side for each of the first set of un-landed vias opposite the first side and connected to the second BEOL layer.

### CROSS-REFERENCE TO RELATED APPLICATION

The present application claims the benefit of U.S. Provisional Patent Application No. 62/700,785, filed on Jul. 19, 2018, and titled “TEST STRUCTURE FOR INTERLAYER INTERCONNECT DEFECTS ON A CHIP,” the disclosure of which is expressly incorporated by reference herein in its entirety.

### BACKGROUND

### Field

The present disclosure generally relates to integrated circuits (ICs). More specifically, the present disclosure relates to a test structure design for screening and/or detection of interlayer metal latent defects on a chip.

### Background

As integrated circuit (IC) technology advances, device (e.g., semiconductor device) geometries are reduced. Reducing the geometry and “pitch” (e.g., spacing) between integrated circuit devices may cause the integrated circuit devices to interfere with each other and affect proper operation.

These integrated circuit devices may include different types of transistors. For example, the devices may include planar transistors, fin-based transistors, or gate all around (GAA) transistors. Fin-based transistors are three-dimensional structures on the surface of a semiconductor substrate. A fin-based transistor, which may be a fin-based metal-oxide-semiconductor field-effect transistor (MOSFET), may be referred to as a FinFET. A nanowire field-effect transistor (FET) is also a three-dimensional structure on the surface of a semiconductor substrate. A nanowire FET includes doped portions of the nanowire that contact a channel region and serve as the source and drain regions of the device. A nanowire FET is also an example of a MOSFET device.

Fabrication of semiconductor integrated circuits specifies that precisely controlled quantities of impurities be introduced into small regions of a semiconductive substrate and that these regions be interconnected to create microelectronic components and integrated circuits. As a result, the manufacture of semiconductor integrated circuits involves a loss of chip yield due to the presence of various defects. An example of a defect that may occur when conductive layers are formed on an integrated circuit is extra material defects. Extra material defects may occur when the conductive structures include material extending beyond predefined boundaries. Such material may extend to another conductive structure, causing a short to be formed between the two conductive structures.

### SUMMARY

A integrated circuit structure has a first test structure with a first set of un-landed vias. The first set of un-landed vias has a first side for each of the first set of un-landed vias proximate to a first BEOL layer (first back-end-of-line layer) of a chip and spaced apart, by a first gap, from the first BEOL layer. Each of the first set of un-landed vias has a first depth that is smaller than a landed depth of a chip via conductively connecting the first BEOL layer to a second BEOL layer of the chip. The first set of un-landed vias has a second side for each of the first set of un-landed vias opposite the first side and connected to the second BEOL layer.

A method of making an integrated circuit structure includes fabricating a first set of landed vias between and connecting a first back-end-of-line (BEOL) layer and a second BEOL layer. Each of the first set of landed vias has a landed depth. The method also includes fabricating a first test structure including a first set of un-landed vias proximate, but not contacting the first BEOL layer. Each of the first set of un-landed vias has a first depth that is smaller than the landed depth of a chip via. The first set of un-landed vias is connected to the second BEOL layer.

A integrated circuit structure includes a first test structure having means for shorting a first BEOL layer (first back-end-of-line layer) of a chip and a second BEOL layer in the presence of a latent defect. The first BEOL layer has a surface that is proximate but spaced apart, by a first gap, from a first side/surface of each of the shorting means. The second BEOL layer has a surface that is on or connected to a second side of each of the shorting means. Each of the shorting means has a first depth that is smaller than a landed depth of a chip via conductively connecting the first BEOL layer to the second BEOL layer of the chip. The second side for each of the shorting means is opposite the first side of each of the shorting means.

A radio frequency (RF) front end module has an integrated circuit structure having a first test structure. The RF front end module includes a first side for each of the first set of un-landed vias proximate to a first BEOL layer (first back-end-of-line layer) of a chip and spaced apart, by a first gap, from the first BEOL layer. Each of the first set of un-landed vias has a first depth that is smaller than a landed depth of a chip via conductively connecting the first BEOL layer to a second BEOL layer of the chip. A second side for each of the first set of un-landed vias is opposite the first side and connected to the second BEOL layer. The RF front end module also includes an antenna coupled to the integrated circuit structure.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates a perspective view of a semiconductor wafer.

FIG. 2 illustrates a cross-sectional view of a die.

FIG. 3 illustrates a cross-sectional view of a metal-oxide-semiconductor field-effect transistor (MOSFET) device.

FIG. 4 illustrates a fin field-effect transistor (FinFET).

FIGS. 5A, 5B, and 5C illustrate a test structure of an integrated circuit, according to aspects of the present disclosure.

FIG. 6 illustrates a integrated circuit structure including at least one conductive test structure including a set of un-landed vias (Via x) placed between a large area of conductive layers (e.g., metal layers (Mx & Mx+1)), in accordance with aspects of the present disclosure.

FIG. 7 illustrates an integrated circuit structure including at least one conductive test structure including a set of un-landed vias (Via x) placed between serpentine/comb/meander conductive layers (e.g., metal layers (Mx & Mx+1)), in accordance with aspects of the present disclosure.

FIG. 8 is a flow diagram illustrating a method of fabricating an integrated circuit structure, in accordance with aspects of the present disclosure.

FIG. 9 is a block diagram showing an exemplary wireless communications system in which a configuration of the disclosure may be advantageously employed.

FIG. 10 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms “wafer” and “die” may be used interchangeably.

The process flow for semiconductor fabrication (e.g., complementary metal-oxide-semiconductor (CMOS) fabrication) of an integrated circuit device may include front-end-of-line (FEOL) processes, middle-of-line (MOL) processes, and back-end-of-line (BEOL) processes. These processes result in three substantially planar layers atop the semiconductor substrate. The FEOL processes may include the set of process steps that form the active devices, such as transistors and diodes. For example, FEOL processes include wafer preparation, isolation, well formation, gate patterning, spacers, and dopant implantation.

The MOL processes may include the set of process steps that enable connection of the transistors to BEOL interconnects. These steps include silicidation and contact formation as well as stress introduction. For example, access to devices, formed during a front-end-of line process, is conventionally provided during middle-of-line processing that provides contacts between the gates and source/drain regions of the devices and back-end-of-line interconnect layers (e.g., M1, M2, etc.). The BEOL processes may include the set of process steps that form the interconnects that tie the independent transistors and form circuits. The BEOL processes include forming interconnects and dielectric layers for coupling to the FEOL devices.

As technology scaling continues, process complexity and increased process steps increase a likelihood of latent defects on chip, For example, latent defects are defects that are not detectable at fabrication screening or at time-zero (TO) screening (e.g., wafer or die probe) but cause failure either at burn-in (which is a very expensive screen test) or in the field. Such latent defects significantly affect logic and radio frequency (RF) circuit functionality or performance because these defects may cause bridging or shorts across adjacent metal levels. Because the latent defects are marginal and can cause circuit failure over time, it is especially important for automotive applications that such defects be minimized or reduced at the source (e.g., silicon chip processing stage or initial electrical testing stage), prior to shipping to customers or prior to expensive screening or potential return merchandise authorizations (RMAs).

Chip designs for automotive applications are specified to pass stringent reliability criteria to meet one defect part per million (DPPM), which specifies extensive and expensive screening/testing of latent defects post-fabrication. Some of the testing/screening includes sophisticated screening at wafer probe, burn-in stress and system-level testing, and extensive automatic test equipment (ATE) testing. These tests can be at a wafer and package level, across different temperature, voltage, and ambient conditions. However, extensive testing at the wafer and package level is expensive. Other solutions include a Bin1 outlier screening methodology (e.g., dynamic part averaging testing (DPAT) and good die/bad neighborhood (GDBN) screening), which causes significant yield loss.

These extensive and expensive screenings for latent defects post-fabrication (e.g., sophisticated screening at wafer probe, burn-in, and extensive automatic test equipment (ATE) testing) do not catch all existing latent defects. Thus, shipped units are exposed to potential on-field failure. Accordingly, continued reduction in latent defects for consumer chip designs is desirable. For example, process innovations are desirable to reduce the incidence of latent defects to further reduce return merchandise authorization (RMA) to near-zero levels.

Aspects of the present disclosure are directed to an integrated circuit structure including a conductive interconnect test structure to detect and prevent latent BEOL defects, such as via or metal barrier weakness and interlayer dielectric voids as well as to monitor interlayer dielectric thickness excursions. In one aspect, the integrated circuit structure includes a first conductive interconnect test structure (or first conductive test structure), which includes a first set of un-landed vias. Each of the first set of un-landed vias has a first side proximate to a first back-end-of-line (BEOL) layer of a chip. The first side is separated from the first BEOL layer by a first gap. The first gap is between the first BEOL layer and the first set of un-landed vias.

Each of the first set of un-landed vias has a second depth that is smaller than a first depth of a chip via (e.g., a process of record (POR) via) configured to conductively connect the first BEOL layer to a second BEOL layer of the chip. For example, each of the first set of un-landed vias also includes a second side opposite the first side and connected to the second BEOL layer above.

In some aspects, the conductive integrated circuit structure may include additional conductive test structures, which include sets of un-landed vias. For example, two different conductive test structures with different sets of un-landed vias are included in the integrated circuit structure. A second conductive test structure may include a second set of un-landed vias. Each of the second set of un-landed vias has a third side proximate to the first BEOL layer. The second set of un-landed vias is separated from the first BEOL layer by a second gap. The second gap is between the first BEOL layer and the second set of un-landed vias. Each of the second set of un-landed vias has a third depth that is smaller than the first depth of the chip via. Each of the second set of un-landed vias also has a fourth side opposite the third side and connected to the second BEOL layer. The second depth is different from the third depth and a dimension of the first gap is different from a dimension of the second gap.

In one aspect of the disclosure, the chip via, the first set of un-landed vias, and the second set of un-landed vias are fabricated with a same etch recipe by leveraging reactive ion etching (RIE) lag. For example, due to RIE lag, the smaller the via size, the shallower the via. The two smaller vias (e.g., the first set of un-landed vias and the second set of un-landed vias) are shorter than the process of record (POR) vias to avoid a short between the first BEOL layer and the second BEOL layer. However, if enough latent defects are present on the first BEOL layer in the first gap or the second gap, then the two smaller vias create a short between the first BEOL layer and the second BEOL layer at T0 (e.g., before packaging) or after packaging or at reduced stress condition (e.g., during dynamic voltage scaling (DVS)).

The conductive test structure may be implemented on a product chip, a foundry test-chip, or an original equipment manufacturer test-chip. The first set of un-landed vias or the second set of un-landed vias are included in one or more rectangular via areas and/or a meandering/serpentine via area. Of course, other shapes are also contemplated.

Detecting the latent defects during the initial electrical testing stage (e.g., wafer-level E-test) avoids more expensive screening later or potential RMAs due to test escapes. Additionally, the conductive test structure can be used to quickly monitor undesired interlayer dielectric (ILD) thickness excursions, during process bring-up, or even in high volume manufacturing. An ILD thickness excursion occurs when the ILD thickness does not meet specifications. For example, when an ILD is thinner than a lower bound of the specifications, then one or more of the un-landed vias (discussed below) can short to a conductive layer (e.g., back-end-of-line (BEOL)) underneath.

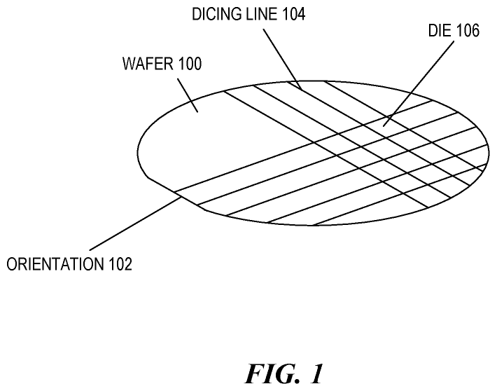

FIG. 1 illustrates a perspective view of a wafer. A wafer 100 may be a semiconductor wafer, or may be a substrate material with one or more layers of material on a surface of the wafer 100. For explanatory purposes a chip, as described herein, may include a wafer or a die. The chip or integrated circuit structure may include the conductive test structure. Accordingly, the chip includes the capability of detecting the latent defects during the initial electrical testing stage (e.g., wafer-level E-test) to avoid more expensive screening later or potential RMAs due to test escapes. The wafer 100 may be a compound material, such as gallium arsenide (GaAs) or gallium nitride (GaN), a ternary material such as indium gallium arsenide (InGaAs), quaternary materials, silicon, quartz, glass, or any material that can be a substrate material. Although many of the materials may be crystalline in nature, polycrystalline or amorphous materials may also be used for the wafer 100. For example, various options for the substrate include a glass substrate, a semiconductor substrate, a core laminate substrate, a coreless substrate, a printed circuit board (PCB) substrate, or other like substrates.

The wafer 100, or layers that are coupled to the wafer 100, may be supplied with materials that enable formation of different types of electronic devices in or on the wafer 100. In addition, the wafer 100 may have an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100, assuming a semiconductor wafer.

Once the wafer 100 has been processed as desired, the wafer 100 is divided up along dicing lines 104. For example, once fabrication of integrated circuits on the wafer 100 is complete, the wafer 100 is divided up along the dicing lines 104, which may be referred to as “dicing streets.” The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form the die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

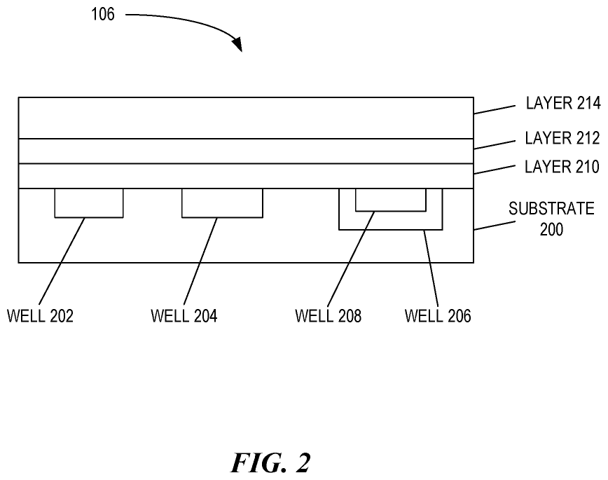

FIG. 2 illustrates a cross-sectional view of a die 106. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200. Alternatively, the substrate may be a semi-insulating substrate, including compound semiconductor transistors. The substrate 200 may include one or more layers of material on a surface of the substrate 200 that includes the conductive test structure. Accordingly, a chip including the substrate and the conductive test structure has the capability of detecting the latent defects during the initial electrical testing stage.

Within a substrate 200 (e.g., a semiconductor substrate), there may be wells 202 and 204, which may be the source and/or drain of a field-effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT), a heterojunction bipolar transistor (HBT), or other like compound semiconductor transistor. The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, implantation, diffusion, deposition, thermal anneals, and other methods may create the structures and devices of the present disclosure.

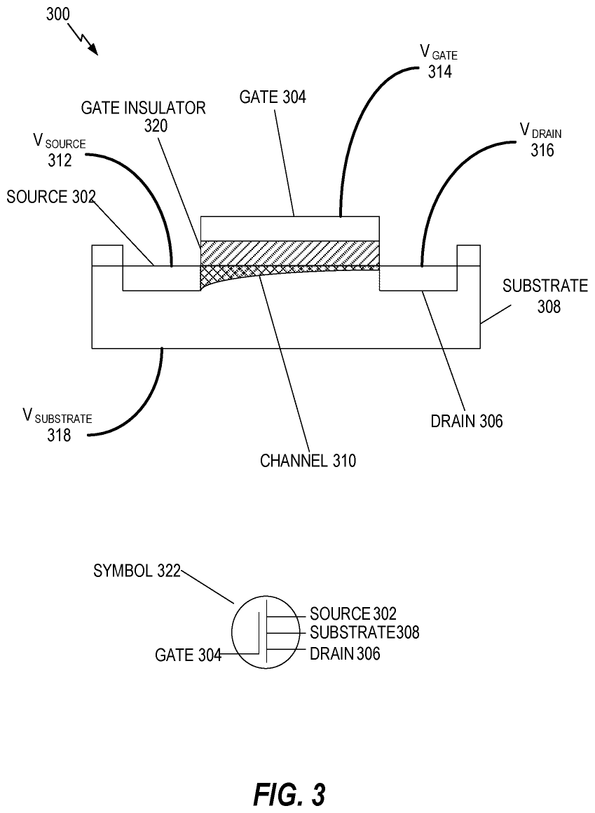

FIG. 3 illustrates a cross-sectional view of a metal-oxide-semiconductor field-effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but the substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in a channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314, or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. A gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon”, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers (e.g., 210-214), or may be in other layers of the die 106.

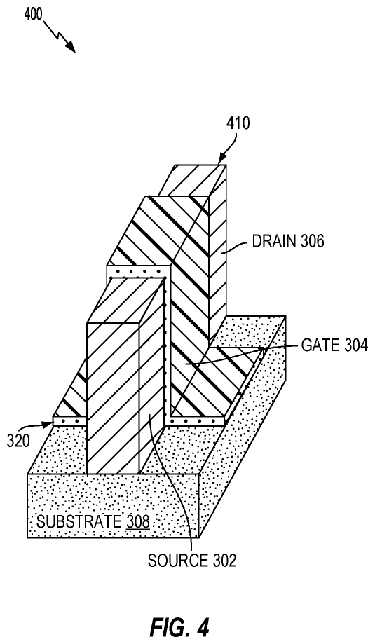

FIG. 4 illustrates a fin-structured FET (FinFET 400) that operates in a similar fashion to the MOSFET device 300 described with respect to FIG. 3. According to aspects of the present disclosure, the FinFET 400 may include multiple gate spacers. A fin 410 in a FinFET 400, however, is grown or otherwise coupled to the substrate 308. The substrate 308 may be a semiconductor substrate or other like supporting layer, for example, comprised of an oxide layer, a nitride layer, a metal oxide layer, or a silicon layer. The fin 410 includes the source 302 and the drain 306. The gate 304 is disposed on the fin 410 and on the substrate 308 through the gate insulator 320. A FinFET transistor is a 3D fin-based metal-oxide-semiconductor field-effect transistor (MOSFET). As a result, the physical size of the FinFET 400 may be smaller than the MOSFET device 300 structure shown in FIG. 3. This reduction in physical size allows for more devices per unit area on the die 106.

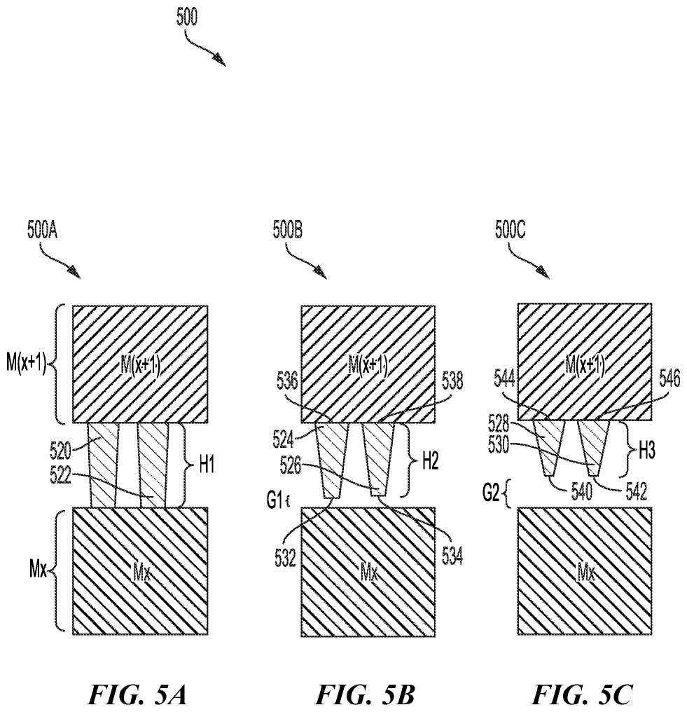

FIGS. 5A, 5B, and 5C illustrate include a chip portion 500A as well as conductive test structures 500B and 500C fabricated on an integrated circuit structure 500 according to aspects of the present disclosure. The integrated circuit structure 500 may include one or more conductive test structures. For example, the integrated circuit structure 500 may include a chip portion 500A, as illustrated in FIG. 5A, a first conductive test structure 500B, as illustrated in FIG. 5B, and a second conductive test structure 500C, as illustrated in FIG. 5C. The integrated circuit structure 500 may be implemented on a product chip, a foundry test-chip, or an original equipment manufacturer test-chip.

FIG. 5A illustrates a chip portion 500A of the integrated circuit structure 500 having a set of process of record (POR) vias (e.g., a first POR via 520 and a second POR via 522) connecting a first back-end-of-line layer Mx of the integrated circuit structure 500 to a second back-end-of-line layer M(x+1) of the integrated circuit structure 500. The first POR via 520 and the second POR via 522 have a first depth H1.

FIG. 5B illustrates a first conductive test structure 500B of the integrated circuit structure 500 having a first set of un-landed vias (e.g., a first un-landed via 524 and a second un-landed via 526) between the first back-end-of-line layer Mx and the second back-end-of-line layer M(x+1), according to aspects of the present disclosure. The first un-landed via 524 has a first side 532 proximate the first back-end-of-line layer Mx and the second un-landed via 526 has a first side 534 proximate the first back-end-of-line layer Mx. In one aspect of the disclosure, each of the first side 532 and the first side 534 is separated from the first back-end-of-line layer Mx by a first gap G1. The first gap G1 is between the first back-end-of-line layer Mx and the first set of un-landed vias (e.g., the first un-landed via 524 and the second un-landed via 526). Each of the first un-landed via 524 and the second un-landed via 526 has a second depth H2 that is smaller than the first depth H1 of the set of process of record (POR)/chip vias. The first un-landed via 524 has a second side 536 opposite the first side 532 that is connected to the second back-end-of-line layer M(x+1). Similarly, the second un-landed via 526 has a second side 538 opposite the first side 534 that is connected to the second back-end-of-line layer M(x+1).

FIG. 5C illustrates a second conductive test structure 500C of the integrated circuit structure 500 having a second set of un-landed vias (e.g., a third un-landed via 528 and a fourth un-landed via 530) between the first back-end-of-line layer Mx and the second back-end-of-line layer M(x+1), according to aspects of the present disclosure. The third un-landed via 528 has a first side 540 proximate the first back-end-of-line layer Mx and the fourth un-landed via 530 has a first side 542 proximate the first back-end-of-line layer Mx. Each of the first side 540 and the first side 542 is separated from the first back-end-of-line layer Mx by a second gap G2. The second gap G2 is between the first back-end-of-line layer Mx and the second set of un-landed vias.

Each of the third un-landed via 528 and the fourth un-landed via 530 has a third depth H3 that is smaller than the first depth H1 of the set of process of record (POR)/chip vias and the second depth H2. The third un-landed via 528 has a second side 544 opposite the first side 540 that is connected to the second back-end-of-line layer M(x+1). Similarly, the fourth un-landed via 530 has a second side 546 opposite the first side 542 that is connected to the second back-end-of-line layer M(x+1). The third depth H3 is smaller than the first depth H1 and the second depth H2, and a dimension of the first gap G1 is smaller than a dimension of the second gap G2.

A size of the vias depends on a metallization level (e.g., back-end-of-line layer). For example, in the densest levels (e.g., lower BEOL layers) of an integrated circuit, a depth (e.g., second depth H2) of the first un-landed via 524 is eighteen nanometers (18 nm) while a depth (e.g., the third depth H3) of the third un-landed via 528 is sixteen nanometers (16 nm). For levels that are less dense (e.g., higher BEOL layers) the second depth H2 of the first un-landed via 524 is thirty six nanometers 36 nm) while the third depth H3 of the third un-landed via 528 is thirty two nanometers (32 nm). The first gap G1 and the second gap G2 may be between ten to twenty nanometers (10-20 nms) where the first gap G1 is smaller than the second gap G2.

In one aspect of the disclosure, the process of record vias, the first set of un-landed vias, and the second set of un-landed vias are fabricated with a same etch recipe by leveraging reactive ion etching (RIE) lag. For example, due to RIE lag, the smaller the via size, the shallower the via. The two smaller vias (e.g., the first set of un-landed vias and the second set of un-landed vias) are shorter than the process of record vias to avoid a short between the first back-end-of-line layer and the second back-end-of-line layer. However, if enough latent defects are present on the first back-end-of-line layer in the first gap G1 or the second gap G2, then the two smaller vias create a short between the first back-end-of-line layer and the second back-end-of-line layer at T0 (e.g., before packaging) or after packaging or at a reduced stress condition (e.g., during dynamic voltage scaling (DVS)).

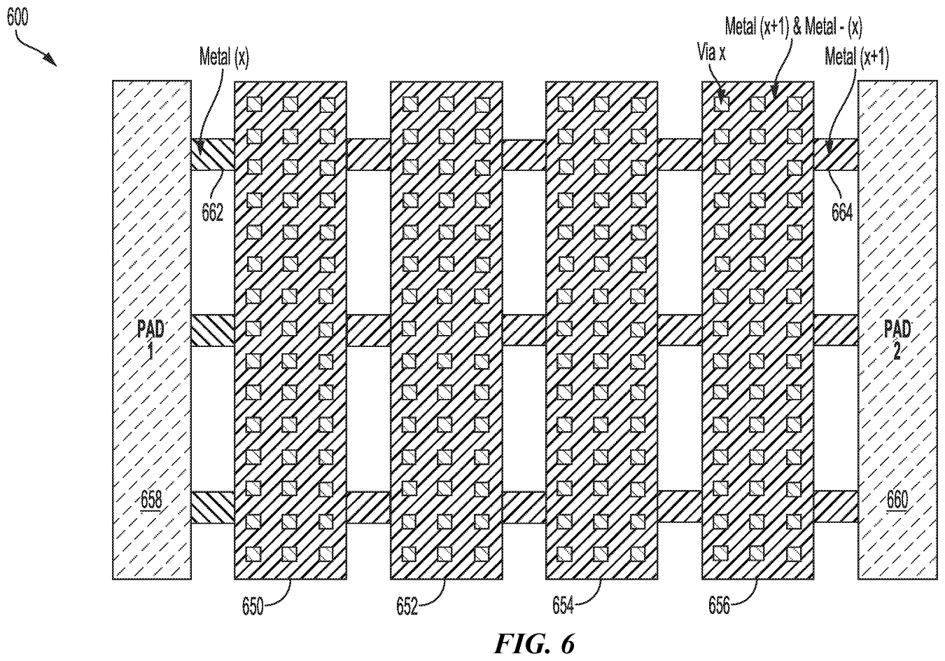

FIG. 6 illustrates a top view of a conductive test structure 600 for a chip where a set of process of record (POR)/chip vias, a first set of un-landed vias, or a second set of un-landed vias are included in one or more via areas. In some aspects, the via areas may be rectangular via areas, square via areas, or other via area shapes. The via areas may include a first via area 650, a second via area 652, a third via area 654, and a fourth via area 656. The number of via areas can be less or more. The via areas may span multiple back-end-of-line layers such as the first back-end-of-line layer Mx and the second back-end-of-line layer M(x+1). Each of the first via area 650, the second via area 652, the third via area 654, and the fourth via area 656 may include multiple vias x from the first set of un-landed vias, the second set of un-landed via or the process of record (POR) vias. Thus, each conductive test structure 600 includes only one type of via (e.g., either the first set of vias, the second set of vias, or the POR vias).

The via areas may be coupled to each other and/or to conductive pads/terminals (e.g., a first contact pad 658 and a second contact pad 660) by back-end-of-line interconnects of the back-end-of-line layers. For example, a first back-end-of-line interconnect or a first terminal 662 in the first back-end-of-line layer Mx is coupled to the first contact pad 658 of the conductive test structure 600 and to the first via area 650. A second back-end-of-line interconnect or a second terminal 664 in the second back-end-of-line layer M(x+1) is coupled to the second contact pad 660 of the conductive test structure 600 and to the fourth via area 656. The first contact pad 658 may be configured to receive charge of a first polarity (e.g., positive) while the second contact pad 660 is configured to receive charge of a second polarity (e.g., negative).

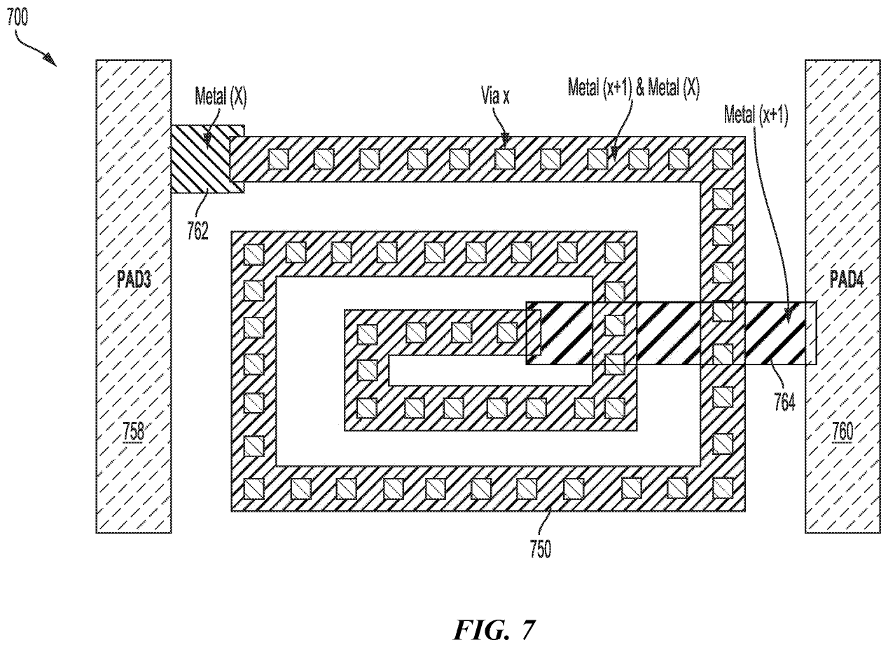

The first set of un-landed vias or the second set of un-landed vias are included in one or more rectangular via areas (as shown in FIG. 6). Of course, other shapes, such as a meandering/serpentine via area illustrated in FIG. 7, are also contemplated.

FIG. 7 illustrates a conductive test structure 700 for a chip where the first set of un-landed vias, the set of process of record (POR)/chip vias, or the second set of un-landed vias are included in a meandering/serpentine via area 750. The metal linewidths of an integrated circuit including a conductive test structure (e.g., conductive test structure 700) are close to minimum design rule values and is representative of a real chip design. The conductive test structure 700 includes a third contact pad 758 in the first back-end-of-line layer Mx and a fourth contact pad 760 in the second back-end-of-line layer M(x+1). The third contact pad 758 is coupled to a third terminal 762 in the first back-end-of-line layer Mx. The third terminal 762 is also coupled to a first end of the meandering/serpentine via area 750. The fourth contact pad 760 is coupled to a fourth terminal 764 in the second back-end-of-line layer M(x+1). The fourth terminal 764 is also coupled to a second end of the meandering via area 750 that is opposite the first end. The meandering/serpentine via area 750 includes multiple vias x, some of which are the process of record (POR)/chip vias, the first set of un-landed vias, or the second set of un-landed vias.

To detect a latent defect, a charge (e.g., current or voltage) of the first polarity is applied to a conductive terminal (e.g., the first terminal 662 or the third terminal 762). The charge of the first polarity is applied through the first contact pad 658 or third contact pad 758. Another charge of the second polarity is applied to or sensed at another conductive terminal (e.g., the second terminal 664 or the fourth terminal 764). The charge of the second polarity is applied through the second contact pad 660 or the fourth contact pad 760. A significant charge (e.g., current or voltage) above some noise floor, between the first back-end-of-line layer Mx and the second back-end-of-line layer M(x+1), where the first set of un-landed vias or a second set of un-landed vias are included, indicates a short between the first back-end-of-line layer Mx and the second back-end-of-line layer M(x+1). For example, the charge above the noise floor may be detected between the second side 536 of the first un-landed via 524 that is connected to the second back-end-of-line layer M(x+1) and the first back-end-of-line layer Mx when there is unwanted conductive material in the gap G1 that shorts the first un-landed via 524 to the first back-end-of-line layer Mx.

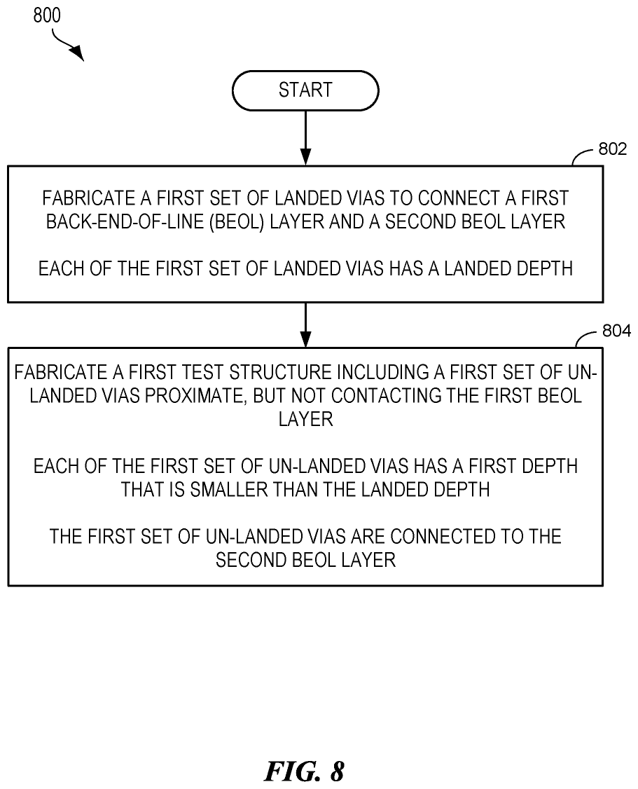

FIG. 8 is a flow diagram illustrating a method 800 of fabricating a conductive test structure device, in accordance with aspects of the present disclosure. The blocks in the method 800 may be performed in or out of the order shown, and in some aspects, can be performed at least in part in parallel.

At block 802, a first set of landed vias is fabricated between and connecting a first back-end-of-line (BEOL) layer and a second BEOL layer. Each of the first set of landed vias has a landed depth. At block 804, a first conductive test structure including a first set of un-landed vias is fabricated. The first set of un-landed vias is fabricated proximate, but not contacting the first BEOL layer of a chip. Each of the first set of un-landed vias has a first depth that is smaller than the landed depth. The first set of un-landed vias are connected to the second BEOL layer.

According to one aspect of the present disclosure, a conductive test structure is described. The conductive test structure includes means for shorting the first BEOL layer and the second BEOL layer in the presence of a latent defect. The shorting means may, for example, be the first un-landed via 524 and/or the second un-landed via 526, as illustrated in FIG. 5B, or the third un-landed via 528 and/or fourth un-landed via 530 as illustrated in FIG. 5C. In another aspect, the aforementioned means may be any module or any apparatus or material configured to perform the functions recited by the aforementioned means.

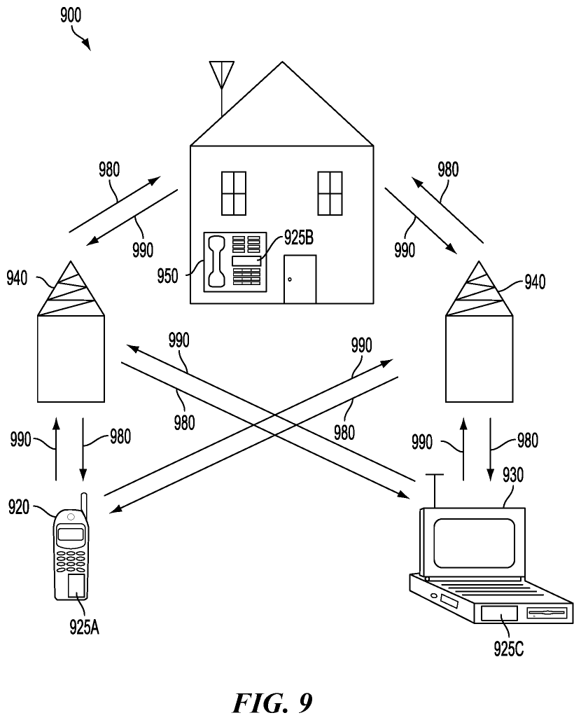

FIG. 9 is a block diagram showing an exemplary wireless communications system 900 in which an aspect of the disclosure may be advantageously employed. For purposes of illustration, FIG. 9 shows three remote units 920, 930, and 950 and two base stations 940. It will be recognized that wireless communications systems may have many more remote units and base stations. Remote units 920, 930, and 950 include IC devices 925A, 925C, and 925B that include at least a portion of the conductive test structure. It will be recognized that other devices including the conductive test structure may also be included in, for example, base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, a remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices including the conductive test structure.

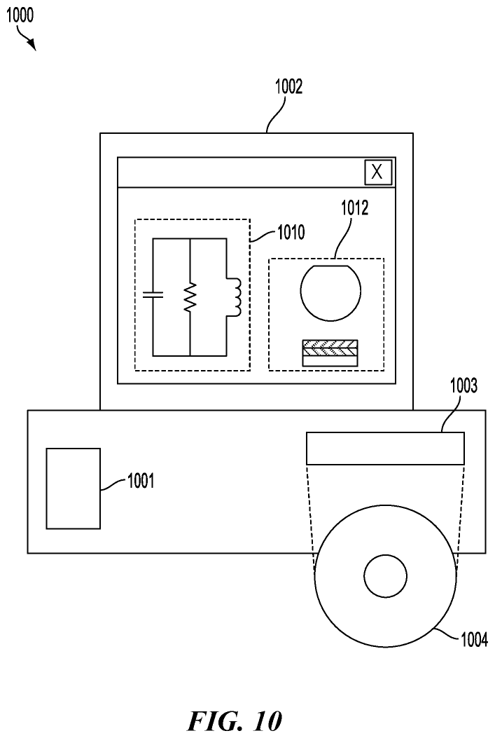

FIG. 10 is a block diagram illustrating a design workstation used for circuit, layout, and logic design of a semiconductor component tested using the conductive test structure disclosed above. A design workstation 1000 includes a hard disk 1001 containing operating system software, support files, and design software such as Cadence or OrCAD. The design workstation 1000 also includes a display 1002 to facilitate a circuit design 1010 or a chip having the conductive test structure. A storage medium 1004 is provided for tangibly storing the circuit design 1010 including the conductive test structure 1012. The circuit design 1010 including the conductive test structure may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit design 1010 or the conductive test structure 1012 by decreasing the number of processes for designing semiconductor wafers.

The accompanying claims and their equivalents are intended to cover such forms or modifications as would fall within the scope and spirit of the protection. For example, the example apparatuses, methods, and systems disclosed herein may be applied to multi-SIM wireless devices subscribing to multiple communications networks and/or communications technologies. The apparatuses, methods, and systems disclosed herein may also be implemented digitally and differentially, among others. The various components illustrated in the figures may be implemented as, for example, but not limited to, software and/or firmware on a processor, ASIC/FPGA/DSP, or dedicated hardware. Also, the features and attributes of the specific example aspects disclosed above may be combined in different ways to form additional aspects, all of which fall within the scope of the present disclosure.

The foregoing method descriptions and the process flow diagrams are provided merely as illustrative examples and are not intended to require or imply that the operations of the method must be performed in the order presented. Certain of the operations may be performed in various orders. Words such as “thereafter,” “then,” “next,” etc., are not intended to limit the order of the operations; these words are simply used to guide the reader through the description of the methods.

The various illustrative logical blocks, modules, circuits, and operations described in connection with the aspects disclosed herein may be implemented as electronic hardware, computer software, or combinations of both. To clearly illustrate this interchangeability of hardware and software, various illustrative components, blocks, modules, circuits, and operations have been described herein generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the various aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of receiver devices, e.g., a combination of a DSP and a microprocessor, a plurality of microprocessors, one or more microprocessors in conjunction with a DSP core, or any other such configuration. Alternatively, some operations or methods may be performed by circuitry that is specific to a given function.

In one or more exemplary aspects, the functions described herein may be implemented in hardware, software, firmware, or any combination thereof. If implemented in software, the functions may be stored as one or more instructions or code on a non-transitory computer-readable storage medium or non-transitory processor-readable storage medium. The operations of a method or algorithm disclosed herein may be embodied in processor-executable instructions that may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include random access memory (RAM), read-only memory (ROM), electrically erasable programmable read-only memory (EEPROM), FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A integrated circuit structure, comprising:
a first test structure comprising,
a first set of un-landed vias comprising:
a first side for each of the first set of un-landed vias proximate to a first BEOL layer (first back-end-of-line layer) of a chip and spaced apart, by a first gap, from the first BEOL layer, in which each of the first set of un-landed vias has a first depth that is smaller than a landed depth of a chip via conductively connecting the first BEOL layer to a second BEOL layer of the chip; and
a second side for each of the first set of un-landed vias opposite the first side and connected to the second BEOL layer.

2. The integrated circuit structure of claim 1, further comprising a second test structure, the second test structure comprising a second set of un-landed vias comprising:
a third side for each of the second set of un-landed vias proximate to the first BEOL layer and spaced apart, by a second gap, from the first BEOL layer, in which each of the second set of un-landed vias has a second depth that is smaller than the landed depth of the chip via; and
a fourth side for each of the second set of un-landed vias opposite the third side and connected to the second BEOL layer, the first depth different from the second depth and a dimension of the first gap different from a dimension of the second gap.

3. The integrated circuit structure of claim 1, in which the first set of un-landed vias is included in a rectangular via area.

4. The integrated circuit structure of claim 1, in which the first set of un-landed vias is included in a meandering via area.

5. The integrated circuit structure of claim 1 between a third BEOL layer and a fourth BEOL layer.

6. A method of making an integrated circuit structure, comprising:
fabricating a first set of landed vias between and connecting a first back-end-of-line (BEOL) layer and a second BEOL layer, each of the first set of landed vias having a landed depth; and
fabricating a first test structure including a first set of un-landed vias proximate, but not contacting the first BEOL layer, in which each of the first set of un-landed vias has a first depth that is smaller than the landed depth of a chip via, the first set of un-landed vias connected to the second BEOL layer.

7. The method of claim 6, further comprising:
fabricating a second test structure comprising a second set of un-landed vias proximate, but not contacting the first BEOL layer, in which each of the second set of un-landed vias has a second depth that is smaller than the first depth, the second set of un-landed vias connected to the second BEOL layer.

8. The method of claim 7, further comprising fabricating the first set of landed vias, the first set of un-landed vias, and the second set of un-landed vias with a same etch recipe by leveraging reactive ion etching (RIE) lag.

9. The method of claim 6, further comprising fabricating the first set of un-landed vias in a rectangular via area.

10. The method of claim 6, further comprising fabricating the first set of un-landed vias in a meandering via area.

11. The method of claim 6, further comprising fabricating additional test structures between a third BEOL layer and a fourth BEOL layer.

12. A integrated circuit structure, comprising:
a first test structure comprising,
means for shorting a first BEOL layer (first back-end-of-line layer) of a chip and a second BEOL layer in the presence of a latent defect, each of the shorting means comprising;
a first side proximate the first BEOL layer and spaced apart, by a first gap, from the first BEOL layer,
a first depth that is smaller than a landed depth of a chip via conductively connecting the first BEOL layer to the second BEOL layer of the chip; and
a second side opposite the first side and connected to the second BEOL layer; and
a second test structure comprising a set of un-landed vias comprising:
a third side for each of the set of un-landed vias proximate to the first BEOL layer and spaced apart, by a second gap, from the first BEOL layer, in which each of the set of un-landed vias has a second depth that is smaller than the landed depth of the chip via; and
a fourth side for each of the set of un-landed vias opposite the third side and connected to the second BEOL layer, the first depth different from the second depth and a dimension of the first gap different from a dimension of the second gap.

13. The integrated circuit structure of claim 12, in which the shorting means is included in a rectangular via area.

14. The integrated circuit structure of claim 12, in which the shorting means is included in a meandering via area.

15. The integrated circuit structure of claim 12, further comprising a plurality of test structures between a third BEOL layer and a fourth BEOL layer.

16. A radio frequency (RF) front end module comprising:
an integrated circuit having a first test structure including a first side for each of a first set of un-landed vias proximate to a first BEOL layer (first back-end-of-line layer) of a chip and spaced apart, by a first gap, from the first BEOL layer, in which each of the first set of un-landed vias has a first depth that is smaller than a landed depth of a chip via conductively connecting the first BEOL layer to a second BEOL layer of the chip, and a second side for each of the first set of un-landed vias opposite the first side and connected to the second BEOL layer; and
an antenna coupled to the integrated circuit.

17. The radio frequency front end module of claim 16, in which the integrated circuit further comprises a second test structure comprising a second set of un-landed vias in which:
a third side for each of the second set of un-landed vias is proximate to the first BEOL layer and spaced apart, by a second gap, from the first BEOL layer, in which each of the second set of un-landed vias has a second depth that is smaller than the landed depth of the chip via; and
a fourth side for each of the second set of un-landed vias is opposite the third side and connected to the second BEOL layer, the first depth different from the second depth and a dimension of the first gap different from a dimension of the second gap.

18. The radio frequency front end module of claim 16, in which the first set of un-landed vias is included in a rectangular via area.

19. The radio frequency front end module of claim 16, in which the first set of un-landed vias is included in a meandering via area.

20. The radio frequency front end module of claim 16, further comprising a plurality of additional test structures between a third BEOL layer and a fourth BEOL layer.
